(19) United States
(12) Patent Application Publication
(10) Pub. No.: US 2026/0103660 A1
(43) Pub. Date: Apr. 16, 2026

(54) WAFER SURFACE CLEANING PROCESS

(71) Applicant: CORNING INCORPORATED, CORNING, NY (US)

(72) Inventors: Dongmei Liu, Changshu City (CN); Chih Yuan Lu, Kaohsiung City (TW); Yong Shen, Cheng Du (CN); Chia Ying Wu, Taichung City (TW)

(21) Appl. No.: 19/354,037

(22) Filed: Oct. 9, 2025

(30) Foreign Application Priority Data
Oct. 16, 2024 (CN) 202411448202.2

(51) Int. Cl. C11D 3/33; C11D 3/04; C11D 3/10; C11D 3/20; C11D 3/36; C11D 3/37; H01L 21/02

(52) U.S. Cl. CPC C11D 3/33; C11D 3/044; C11D 3/10; C11D 3/2079; C11D 3/2082; C11D 3/362; C11D 3/3707; C11D 3/3765; H10P 70/20

(57) ABSTRACT

A method of removing particles from a surface of a wafer, the method including cleaning the wafer with an aqueous first solution. The aqueous first solution including a mixture of a first detergent, a second detergent, and a third detergent. The first detergent including an aqueous solution comprising a pH buffer, an inorganic alkali, a wetting and emulsifying agent, and a chelating agent. The second detergent including an aqueous solution comprising an emulsifier, a pH buffer, an inorganic alkali, a double electric agent, and a chelating agent. The third detergent including an aqueous solution comprising a pH buffer, a wetting and penetration agent, an antistatic and emulsifying agent, and a chelating agent.

This Application claims priority from Patent Application in P. R. of China Serial Number 202411448202.2, filed on Oct. 16, 2024, and which is incorporated by reference herein in its entirety.

### BACKGROUND

During fabrication of wafers (e.g. glass, silicon, etc.), the wafers may be polished to provide the desired surface properties. After polishing, particles and other matter may be disposed on the surfaces of the wafers. Various processes have been developed to clean wafers after polishing.

### SUMMARY

One aspect of the present disclosure is a method of removing particles from a surface of a wafer, the method comprising cleaning the wafer with an aqueous first solution comprising a mixture of a first detergent, a second detergent, and a third detergent. The first detergent comprises an aqueous solution comprising a pH buffer, an inorganic alkali, a wetting and emulsifying agent, and a chelating agent, the second detergent comprises an aqueous solution comprising an emulsifier, a pH buffer, an inorganic alkali, a double electric agent, and a chelating agent, and the third detergent comprises an aqueous solution comprising a pH buffer, a wetting and penetration agent, an antistatic and emulsifying agent, and a chelating agent.

Another aspect of the present disclosure is a cleaning system for removing polishing particles from surfaces of wafers that have been polished, the cleaning system comprising a tank containing an aqueous first solution comprising a mixture of a first detergent, a second detergent, and a third detergent. The first detergent comprises an aqueous solution comprising a pH buffer, an inorganic alkali, a wetting and emulsifying agent, and a chelating agent, the second detergent comprises an aqueous solution comprising an emulsifier, a pH buffer, an inorganic alkali, a double electric agent, and a chelating agent, and the third detergent comprises an aqueous solution comprising a pH buffer, a wetting and penetration agent, an antistatic and emulsifying agent, and a chelating agent.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary and are intended to provide an overview or framework to understanding the nature and character of the claims. The accompanying drawings are included to provide a further understanding and are incorporated in and constitute a part of this specification. The drawings illustrate one or more embodiments, and together with the description serve to explain principles and operation of the various embodiments.

### BRIEF DESCRIPTION OF THE DRAWINGS

FIG. 1 is a partially schematic view of comparative sample wafers showing particles on the surfaces of the wafers after the sample wafers were cleaned utilizing conventional cleaning processes;

FIG. 2 is a schematic showing a wafer cleaning process according to aspects of the present disclosure;

FIG. 3 is a partially schematic view of wafers cleaned according to the process of FIG. 2 and according to aspects of the present disclosure;

FIG. 4A is a schematic showing the functional aspects of cleaning agents according to aspects of the present disclosure;

FIG. 4B is a schematic showing the functional aspects of cleaning agents according to aspects of the present disclosure;

FIG. 4C is a schematic showing the functional aspects of cleaning agents according to aspects of the present disclosure;

FIG. 4D is a schematic showing the functional aspects of cleaning agents according to aspects of the present disclosure;

FIG. 5 is a schematic showing the organic detergent functions to remove the free particles from the wafer surface according to aspects of the present disclosure;

FIG. 6 is a schematic showing a function of an emulsifier according to aspects of the present disclosure;

FIG. 7 is a schematic showing a function of the penetrating agent according to aspects of the present disclosure;

FIG. 8 is a schematic showing a function of the double electric according to aspects of the present disclosure;

FIG. 9 is a schematic showing the function of the anti-static agent according to aspects of the present disclosure; and

FIG. 10 is a schematic showing the function of the wetting agent according to aspects of the present disclosure.

### DETAILED DESCRIPTION

In the following detailed description, for purposes of explanation and not limitation, example embodiments disclosing specific details are set forth to provide a thorough understanding of various principles of the present disclosure. However, it will be apparent to one having ordinary skill in the art, having had the benefit of the present disclosure, that the present disclosure may be practiced in other embodiments that depart from the specific details disclosed herein. Moreover, descriptions of well-known devices, methods and materials may be omitted so as not to obscure the description of various principles of the present disclosure. Finally, wherever applicable, like reference numerals refer to like elements.

Ranges can be expressed herein as from “about” one particular value, and/or to “about” another particular value. As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an endpoint of a range, the disclosure should be understood to include the specific value or endpoint referred to. Whether or not a numerical value or endpoint of a range in the specification recites “about,” the numerical value or endpoint of a range is intended to include two embodiments: one modified by “about,” and one not modified by “about.” It will be further understood that the endpoints of each of the ranges are significant both in relation to the other endpoint, and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other, for example within about 5% of each other, or within about 2% of each other.

As used herein, the term “dispose” includes coating, depositing and/or forming a material onto a surface. The disposed material may constitute a layer, as defined herein. The phrase “disposed on” includes the instance of forming a material onto a surface such that the material is in direct contact with the surface and also includes the instance where the material is formed on a surface, with one or more intervening material(s) between the disposed material and the surface. The intervening material(s) may constitute a layer, as defined herein.

Directional terms as used herein—for example up, down, right, left, front, back, top, bottom—are made only with reference to the figures as drawn and/or to any specific orientation described herein and are not intended to imply absolute orientation.

Unless otherwise expressly stated, it is in no way intended that any method set forth herein be construed as requiring that its steps be performed in a specific order. Accordingly, where a method claim does not actually recite an order to be followed by its steps, or it is not otherwise specifically stated in the claims or descriptions that the steps are to be limited to a specific order, it is in no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

As used herein, the singular forms “a,” “an” and “the” include plural referents unless the context clearly dictates otherwise. Thus, for example, reference to a “component” includes embodiments having two or more such components, unless the context clearly indicates otherwise.

As discussed below, “zeta potential” is a physical property which is exhibited by particles in suspension, macromolecules, or material surfaces. It is an indicator of the stability of colloidal dispersion of the particles, such that particles with a high zeta potential (negative or positive) form electrically stabilized colloids while particles with a low zeta potential tend to coagulate. As used herein, zeta potential is measured using electrophoresis in which an electric field is applied across the particles in suspension. Particles with a high zeta potential will migrate towards the electrode of opposite charge with a velocity proportional to the magnitude of its zeta potential.

During wafer manufacturing, glass wafers may go from a wire saw to polishing. The glass wafers may, optionally, have diameters of about 200 mm, 300 mm, or other suitable size, and may have a refractive index of about 2.0 or greater. It will be understood, however, that the present disclosure is not limited to these examples, and a cleaning process according to the present disclosure may be utilized in connection with virtually any glass wafers. After the wafers are polished, the wafers are cleaned in a washer to remove surface particles and/or stains. Preferably, the wafers are cleaned so that a particle count on the cleaned wafers is zero particles having a size greater than or equal to 5 microns (5 μm), including on both sides of the wafers. Low (e.g. zero) particle counts may be required if, for example, surfaces of the wafers are coated in a subsequent step.

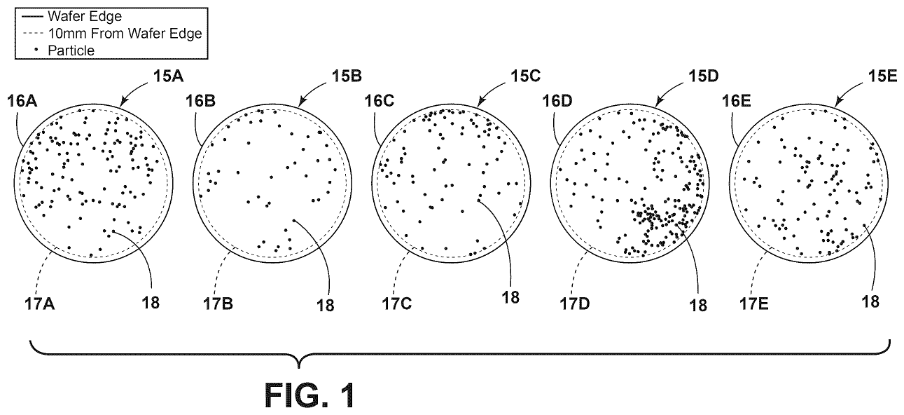

Examples of comparative wafers 15A-15E that were cleaned utilizing conventional processes are shown schematically in FIG. 1. The conventional cleaning processes utilized commercially available detergents that do not encompass the embodiments disclosed herein. FIG. 1 shows the scanning results of the areas inside of the dashed lines 17A-17E on the comparative wafers. A ZScanner™ 800 scanning device was used to determine the number of particles on the comparative wafers and within dashed lines 17A-17E. The areas inside of the dashed lines 17A-17E do not include the 10 mm region between edges 16A-16E of comparative wafers 15A-15E and dashed lines 17A-17E, respectively. The number of particles 18 having a size greater than or equal to 5 microns within dashed lines 17A-17E was determined for each comparative wafer 15A-15E. Each of the comparative wafers 15A-15E included from about 30 to about 150 particles 18 on each side of the wafers. Thus, the conventional cleaning process utilized to clean comparative wafers 15A-15E resulted in a significant number of particles having a size greater than or equal to 5 microns on the surfaces of the wafers after the conventional cleaning process. Due to the significant number of particles 18, downstream coating of the comparative wafers 15A-15E may result in uneven or non-uniform coating layers on the wafers.

The particle size of 5 microns may comprise a threshold particle size, in some embodiments, such that particles less than 5 microns are not considered to affect downstream coating processes. However, any suitable threshold size may be used (e.g. larger or smaller than 5 microns) for a particular application, and the present disclosure is not limited to a specific particle size.

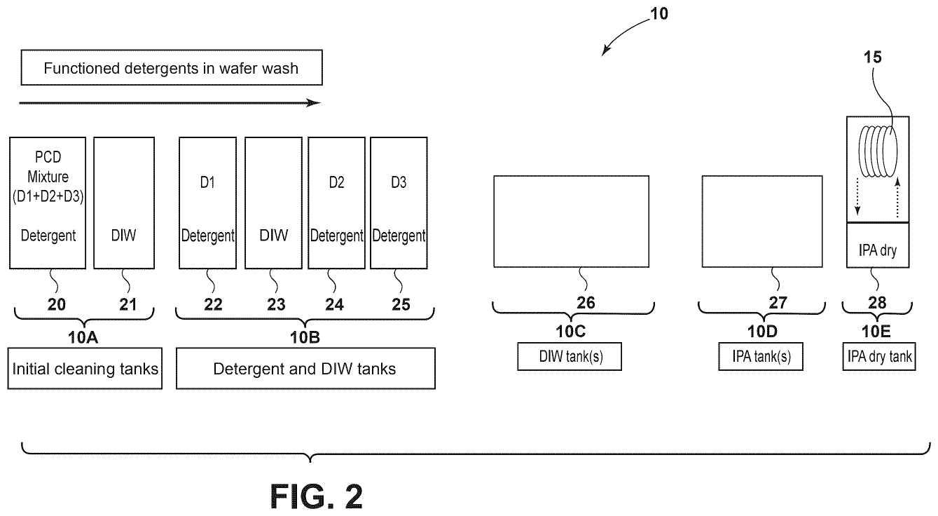

As discussed in more detail below in connection with FIG. 2, cleaning process 10 according to embodiments of the present disclosure may utilize an aqueous first solution that may comprise a mixture of a first detergent D1, a second detergent D2, and a third detergent D3. The first aqueous solution may also be referred to herein as a precleaning detergent mixture (PCD). As also discussed further below, the first aqueous solution may comprise the first detergent D1, the second detergent D2, and the third detergent D3 in specific ratios and amounts.

The first detergent D1 may comprise a pH buffer from about 1 wt. % or greater, or about 2 wt. % or greater, or about 3 wt. % or greater, or about 4 wt. % or greater, or about 5 wt. % or greater, or about 10 wt. % or less, or about 9 wt. % or less, or about 8 wt. % or less, or about 7 wt. % or less, or about 6 wt. % or less, or from about 1 wt. % to about 10 wt. %, or about 2 wt. % to about 8 wt. %, or about 4 wt. % to about 7 wt. %, or about 5 wt. % to about 6 wt. %, or any range encompassing these endpoints. In embodiments, the pH buffer comprises sodium carbonate such as, for example, carbonic acid sodium salt (CH₂O₃·2Na). The first detergent D1 may also comprise a pH modifier from about 10 wt. % or greater, or about 11 wt. % or greater, or about 12 wt. % or greater, or about 13 wt. % or greater, or about 14 wt. % or greater, or about 20 wt. % or less, or about 18 wt. % or less, or about 16 wt. % or less, or about 14 wt. % or less, or from about 10 wt. % to about 20 wt. %, or about 12 wt. % to about 18 wt. %, or about 14 wt. % to about 16 wt. %, or about 12 wt. % to about 16 wt. %, or any range encompassing these endpoints. In embodiments, the pH modifier comprises an inorganic alkali such as, for example, sodium hydroxide (NaOH).

The first detergent D1 may also comprise a wetting agent/emulsifier from about 2 wt. % or greater, or about 4 wt. % or greater, or about 6 wt. % or greater, or about 8 wt. % or greater, or about 18 wt. % or less, or about 16 wt. % or less, or about 14 wt. % or less, or about 12 wt. % or less, or about 10 wt. % or less, or from about 2 wt. % to about 18 wt. %, or about 4 wt. % to about 16 wt. %, or about 6 wt. % to about 14 wt. %, or about 8 wt. % to about 14 wt. %, or about 6 wt. % to about 10 wt. %, or about 8 wt. % to about 10 wt. %, or any range encompassing these endpoints. In embodiments, the wetting agent/emulsifier comprises disodium succinate (C₄H₆O₄·2Na). The first detergent D1 may also comprise a chelating agent from about 2 wt. % or greater, or about 4 wt. % or greater, or about 5 wt. % or greater, or about 6 wt. % or greater, or about 18 wt. % or less, or about 16 wt. % or less, or about 14 wt. % or less, or about 12 wt. % or less, or from about 2 wt. % to about 18 wt. %, or about 4 wt. % to about 16 wt. %, or about 6 wt. % to about 14 wt. %, or about 8 wt. % to about 12 wt. %, or about 5 wt. % to about 12 wt. %, or about 6 wt. % to about 10 wt. %, or any range encompassing these endpoints. In embodiments, the chelating agent is ethylenediaminetetraacetic acid (C₁₀H₁₆N₂O₈). The remainder of the first detergent D1 may comprise water (e.g., deionized water).

The second detergent D2 may comprise an emulsifier from about 1 wt. % or greater, or about 2 wt. % or greater, or about 3 wt. % or greater, or about 4 wt. % or greater, or about 5 wt. % or greater, or about 6 wt. % or less, or about 5 wt. % or less, or about 4 wt. % or less, or from about 1 wt. % to about 6 wt. %, or about 2 wt. % to about 5 wt. % or from about 3 wt. % to about 4 wt. %, or about 1 wt. % to about 3 wt. %, or any range encompassing these endpoints. In embodiments, the emulsifier is oleic acid such as sodium oleate (C₁₈H₃₄O₂·Na).

The second detergent D2 may also comprise a pH buffer from about 4 wt. % or greater, or about 4 wt. % or greater, or about 6 wt. % or greater, or about 8 wt. % or greater, or about 16 wt. % or less, or about 14 wt. % or less, or about 12 wt. % or less, or from about 6 wt. % to about 16 wt. %, or about 8 wt. % to about 14 wt. %, or about 8 wt. % to about 12 wt. %, or about 10 wt. % to about 12 wt. %, or any range encompassing these endpoints. In embodiments, the pH buffer comprises sodium carbonate such as, for example, carbonic acid sodium salt (CH₂O₃·2Na). The second detergent D2 may also comprise a pH modifier from about 6 wt. % or greater, or about 8 wt. % or greater, or about 10 wt. % or greater, or about 20 wt. % or less, or about 18 wt. % or less, or about 16 wt. % or less, or about 14 wt. % or less, or from about 8 wt. % to about 20 wt. %, or about 10 wt. % to about 18 wt. %, or about 12 wt. % to about 16 wt. %, or about 10 wt. % to about 15 wt. %, or any range encompassing these endpoints. In embodiments, the pH modifier comprises an inorganic alkali such as, for example, sodium hydroxide (NaOH).

The second detergent D2 may also comprise a double electric agent from about 1 wt. % or greater, or about 2 wt. % or greater, or about 3 wt. % or greater, or about 4 wt. % or greater, or about 8 wt. % or less, or about 7 wt. % or less, or about 6 wt. % or less, or from about 1 wt. % to about 8 wt. %, or about 2 wt. % to about 7 wt. %, or about 3 wt. % to about 6 wt. %, or about 4 wt. % to about 5 wt. %, or about 2 wt. % to about 6 wt. %, or any range encompassing these endpoints. In embodiments, the double electric agent is an acrylic acid homopolymer such as, for example, 2-propenoic acid, 2-hydroxy-, homopolymer, sodium salt ((C₃H₄O₃)ₓ·xNa).

The second detergent D2 may also comprise a chelating agent from about 2 wt. % or greater, or about 4 wt. % or greater, or about 5 wt. % or greater, or about 6 wt. % or greater, or about 7 wt. % or greater, or about 18 wt. % or less, or about 16 wt. % or less, or about 14 wt. % or less, or about 12 wt. % or less, or from about 2 wt. % to about 18 wt. %, or about 4 wt. % to about 16 wt. %, or about 6 wt. % to about 14 wt. %, or about 8 wt. % to about 12 wt. %, or about 7 wt. % to about 12 wt. %, or about 6 wt. % to about 10 wt. %, or any range encompassing these endpoints. In embodiments, the chelating agent is ethylenediaminetetraacetic acid (C₁₀H₁₆N₂O₈). The remainder of the second detergent D2 may comprise water (e.g., deionized water).

The third detergent D3 may comprise a pH buffer from about 1 wt. % or greater, or about 2 wt. % or greater, or about 3 wt. % or greater, or about 4 wt. % or greater, or about 5 wt. % or greater, or about 14 wt. % or less, or about 2 wt. % or less, or about 10 wt. % or less, or about 8 wt. % or less, or about 6 wt. % or less, or from about 1 wt. % to about 14 wt. %, or about 2 wt. % to about 2 wt. %, or about 4 wt. % to about 12 wt. %, or about 5 wt. % to about 10 wt. %, or any range encompassing these endpoints. In embodiments, the pH buffer comprises sodium carbonate such as, for example, carbonic acid sodium salt (CH₂O₃·2Na).

The third detergent D3 may also comprise a wetting/penetration agent from about 1 wt. % or greater, or about 2 wt. % or greater, or about 4 wt. % or greater, or about 6 wt. % or greater, or about 20 wt. % or less, or about 18 wt. % or less, or about 16 wt. % or less, or about 14 wt. % or less, or about 12 wt. % or less, or from about 1 wt. % to about 20 wt. %, or about 2 wt. % to about 18 wt. %, or about 4 wt. % to about 16 wt. %, or about 6 wt. % to about 14 wt. %, or about 8 wt. % to about 12 wt. %, or about 10 wt. % to about 12 wt. %, or about 1 wt. % to about 8 wt. %, or about 1 wt. % to about 7 wt. %, or about 1 wt. % to about 6 wt. %, or any range encompassing these endpoints. In embodiments, the wetting/penetration agent comprises an ether such as, for example polyoxyethylene isostearyl ether (C₂H₄O)ₙC₁₈H₃₈O) and/or ethylene oxide-propylene oxide copolymer glycerol ether (C₃H₈O₃·3(C₃H₆O·C₂H₄O)ₓ). In some embodiments, the wetting/penetration agent comprises a first ether and a second ether, such as polyoxyethylene isostearyl ether (C₂H₄O)ₙC₁₈H₃₈O) as the first ether and ethylene oxide-propylene oxide copolymer glycerol ether (C₃H₈O₃·3(C₃H₆O·C₂H₄O)ₓ) as the second ether. The wetting/penetration agent may comprise the same or different amounts of the first ether and the second ether.

The third detergent D3 may also comprise an anti-static agent/emulsifier from about 5 wt. % or greater, or about 7 wt. % or greater, or about 9 wt. % or greater, or about 20 wt. % or less, or about 18 wt. % or less, or about 16 wt. % or less, or about 14 wt. % or less, or from about 5 wt. % to about 20 wt. %, or about 7 wt. % to about 18 wt. %, or about 9 wt. % to about 16 wt. %, or about 10 wt. % to about 14 wt. %, or about 12 wt. % to about 14 wt. %, or about 9 wt. % to about 13 wt. %, or any range encompassing these endpoints. In embodiments, the anti-static agent/emulsifier is phosphoric acid, dodecyl ester, potassium salt (C₁₂H₂₆O·xH₃O₄P·Xk).

The third detergent D3 may also comprise a chelating agent from about 2 wt. % or greater, or about 4 wt. % or greater, or about 5 wt. % or greater, or about 6 wt. % or greater, or about 7 wt. % or greater, or about 18 wt. % or less, or about 16 wt. % or less, or about 14 wt. % or less, or about 12 wt. % or less, or from about 2 wt. % to about 18 wt. %, or about 4 wt. % to about 16 wt. %, or about 6 wt. % to about 14 wt. %, or about 8 wt. % to about 12 wt. %, or about 8 wt. % to about 13 wt. %, or about 6 wt. % to about 10 wt. %, or any range encompassing these endpoints. In embodiments, the chelating agent is ethylenediaminetetraacetic acid (C₁₀H₁₆N₂O₈). The remainder of the third detergent D3 may comprise water (e.g., deionized water).

Exemplary embodiments of the first detergent D1, the second detergent D2, and the third detergent D3 are provided in Table 1 below.

TABLE 1

| | | First | Second | Third |
|---|---|---|---|---|
| Function | Exemplary Chemical | Detergent D1 | Detergent D2 | Detergent D3 |
| Emulsifier | Sodium oleate | — | 1 wt. % to 3 | — |
| | (C₁₈H₃₄O₂•Na) | | wt. % | |
| pH Buffer | Carbonic Acid Sodium Salt | 4 wt. % to | 8 wt. % to | 5 wt. % to |
| | (CH₂O₃•2Na) | 7 wt. % | 12 wt. % | 10 wt. % |
| pH Modifier | Sodium hydroxide (NaOH) | 12 wt. % to | 10 wt. % | — |
| | | 16 wt. % | 15 wt. % | |
| Wetting | Disodium succinate | 6 wt. % to | | — |
| Agent/Emulsifier | (C₄H₆O₄•2Na) | 10 wt. % | | |
| Wetting/Penetration | Polyoxyethylene isostearyl | — | — | 1 wt. % to |
| Agent | ether (C₂H₄O)ₙC₁₈H₃₈O) | | | 6 wt. % |
| Wetting/Penetration | Ethylene oxide-propylene | — | — | 1 wt. % to |
| Agent | oxide copolymer glycerol | | | 7 wt. % |
| | ether | | | |
| | (C₃H₈O₃•3(C₃H₆O•C₂H₄O)ₓ) | | | |
| Anti-Static | Phosphoric acid, dodecyl | — | — | 9 wt. % to |
| Agent/Emulsifier | ester, potassium salt | | | 13 wt. % |
| | (C₁₂H₂₆O•xH₃O₄P•Xk) | | | |
| Double Electric | 2-Propenoic acid, 2- | — | 2 wt. % to | — |
| Agent | hydroxy-, homopolymer, | | 6 wt. % | |
| | sodium salt | | | |
| | ((C₃H₄O₃)ₓ•xNa) | | | |
| Chelating Agent | Ethylenediaminetetraacetic | 5 wt. % | 7 wt. % to | 8 wt. % |
| | acid (C₁₀H₁₆N₂O₈) | 12 wt. % | 12 wt. % | 13 wt. % |
| Water | H₂O | 55 wt. % to | 52 wt. % to | 51 wt. % to |
| | | 73 wt. % | 72 wt. % | 76 wt. % |

The aqueous first solution (the PCD mixture) may comprise the first detergent D1, the second detergent D2, and the third detergent D3 in the following ratios: 1:1:2 to 1:1:5, or 1:1:3 to 1:1:4. In embodiments, the aqueous first solution may comprise the first detergent D1 in an amount from about 15 wt. % to about 35 wt. %, or about 20 wt. % to about 30 wt. %, or about 25 wt. % to about 30 wt. %. In embodiments, the aqueous first solution may comprise the second detergent D2 in an amount from about 15 wt. % to about 35 wt. %, or about 20 wt. % to about 30 wt. %, or about 25 wt. % to about 30 wt. %. In embodiments, the aqueous first solution may comprise the third detergent D3 in an amount from about 40 wt. % to about 60 wt. %, or about 45 wt. % to about 55 wt. %, or about 50 wt. % to about 55 wt. %. In some embodiments, the aqueous first solution may comprise the same amounts (or substantially the same amounts) of the first detergent D1 and the second detergent D2. Furthermore, in some embodiments, the aqueous first solution may comprise more of the third detergent D3 than of either the first detergent D1 or the second detergent D2.

With reference again to FIG. 2, cleaning process 10 may comprise cleaning the wafers in a series of steps or stages 10A-10E. Each step or stage 10A-10E may utilize one or more cleaning devices which may comprise cleaning tanks having cleaning solutions therein. One or more of the tanks may comprise ultrasonic cleaning tanks with filtration systems to remove particles from the liquid after the particles are removed from the surfaces of the wafers. Steps 10A-10E will each be described in more detail below.

The wafers are first exposed to a polishing process, which may cause the formation of particles (e.g., abrasive particles). These particles may reside on surface(s) of the wafers following the polishing process. In embodiments, the particles have a size greater than or equal to 5 microns. Cleaning process 10 removes such particles from the wafers. Cleaning process 10 comprises cleaning the wafers at step 10A by immersing the wafers in the aqueous first solution (the PCD mixture) in tank 20 to remove particles from the wafers. More specifically, the cleaning at step 10A loosens the particles from the surface(s) of the wafers. As discussed further below, the cleaning at step 10A changes the properties of the wafers so that the particles are less attracted to the wafer surfaces and more easily dislodged from the wafer surfaces. It is noted that tank 20 may comprise a single tank or a plurality of tanks. As discussed in more detail below, the use of the aqueous first solution provides significantly improved results compared to conventional processes that do not utilize the aqueous first solution of the present disclosure.

Step 10A of process 10 further comprises, in embodiments, rinsing the wafers with deionized water (DIW) in tank 21 to remove the aqueous first solution and to remove the loosened particles from the surface(s) of the wafers. It is noted that tank 21 may comprise a single tank or a plurality of tanks.

After completion of step 10A of process 10, a majority of the particles may be removed and rinsed away from the surface(s) of the wafers. The subsequent steps of process 10 provide additional cleaning and rinsing of the wafers to remove additional particles from the wafers.

At step 10B of process 10, the wafers are sequentially positioned in one or more tanks 22-25 for further washing of the particles from the surface(s) of the wafers. For example, one or more tanks 22-25 may comprise one or more detergents to perform coarse cleaning to remove relatively larger particles (e.g., about 5 microns or greater) and one or more tanks 22-25 may comprise one or more detergents to perform a fine wash to remove relatively smaller particles (e.g., about 5 microns or smaller). In some embodiments, such as the embodiment shown in FIG. 2, tank 22 comprises the first detergent D1 for coarse cleaning to remove the relatively larger particles. Tank 22 may comprise a single tank or a plurality of tanks. The coarse cleaning may be followed by rinsing with water, such as deionized water (DIW) to rinse off the wafers. In the embodiment shown in FIG. 2, tank 23 comprises deionized water to rinse off any remaining first detergent D1 from the surface(s) of the wafers. Tank 22 may comprise a single tank or a plurality of tanks. The coarse cleaning of the wafers (followed by the subsequent water rinse) may be followed by a fine wash to remove the relatively smaller particles. In some embodiments, such as the embodiment shown in FIG. 2, tank 24 comprises the second detergent D2 to provide a fine wash to remove the relatively smaller particles. Tank 24 may comprise a single tank or a plurality of tanks. The fine wash of the wafers may be followed by another rinsing step. In some embodiments, such as the embodiment shown in FIG. 2, tank 25 comprises the third detergent D3 to conduct this rinsing step. More specifically, the third detergent D3 catches (binds to) organic impurities to remove residual first and second detergents D1 and D2 that may remain from tanks 22 and 24. In general, the third detergent D3 may have increased wetting/penetration relative to the first and second detergents D1 and D2 due to the wetting/penetration agents polyoxyethylene isostearyl ether (C₂H₄O)ₙC₁₈H₃₈O) and ethylene oxide-propylene oxide copolymer glycerol ether (C₃H₈O₃·3(C₃H₆O·C₂H₄O)ₓ) of the third detergent D3. Tank 25 may comprise a single tank or a plurality of tanks.

The cleaning detergent utilized in tank 22 (for example, the first detergent D1), may have a pH from about 11 to about 14. Such allows for the cleaning detergent (e.g., the first detergent D1) to have a higher zeta potential than the abrasive particles on the wafers. Therefore, the cleaning detergent causes the abrasive particles to become dislodged and to be pushed away from the surface(s) of the wafers due to the lower zeta potential of the abrasive particle. Furthermore, in embodiments that utilize the first detergent D1 in tank 22, the chelating agent (e.g., ethylenediaminetetraacetic acid) of the first detergent D1 catches (binds to) metal ions and/or residual abrasives on the wafer surface(s). Thus, most or all of the abrasive particles remaining after the first cleaning step 10A in tanks 20 and 21 are removed in tank 22.

Each of step 10A and step 10B of process 10 may comprise more or less steps than specifically shown in FIG. 2. For example, additional tanks (not shown) may be utilized between tanks 20 and 21, and/or between tanks 22 and 23, and/or between tanks 23 and 24, and/or between tanks 24 and 25, or fewer total tanks may be utilized. In embodiments, additional tanks containing the first detergent D1, the second detergent D2, and/or the third detergent D3 could also be utilized in step 10A and/or step 10B. Still further, the sequence of the tanks 20-25 may be varied. For example, in embodiments, tank 24 may comprise the third detergent D3 and tank 25 may comprise the second detergent D2. Similarly, a tank comprising the first detergent D1 may be utilized after one or more tanks comprising the second detergent D2 and/or the second detergent D3.

It is also contemplated in some embodiments, process 10 does not comprise step 10B. Therefore, the abrasive particles are removed utilizing step 10A of process 10 without the added step 10B.

In embodiments disclosed herein, the wafers may be submerged in the cleaning solution in each of tanks 20-25. For example, wafers may be completely submerged in the cleaning solution such that all surfaces of the wafers are in contact with the cleaning solution in the respective tank.

Still referring to FIG. 2, after the wafers are washed in tank 25, the wafers are then rinsed at step 10C. In embodiments, the rinsing of the wafers at step 10C comprises submerging the wafers in deionized water (DIW) in tank 26. It is noted that tank 26 may comprise a single tank or a plurality of tanks.

Process 10 may further comprise step 10D in which the wafers are cleaned with isopropyl alcohol (IPA). For example, one or more tanks 27 may comprise IPA to further clean the wafers. Step 10E of process 10 may comprise a drying step in which the wafers are dried using, for example, drying tank 28. In some embodiments, the drying step may be an IPA drying process in which IPA vapor is introduced into a drying chamber of drying tank 28. Then a surface tension gradient is established between the IPA vapor and water particles on the surface(s) of the wafers, causing the water particles to flow off the wafers, leaving the wafer surface(s) clean and dry.

As discussed above, process 10 may comprise more or less steps than specifically shown in FIG. 2. Furthermore, the order of the steps may be re-arranged and altered. It is also noted that tanks 20-28 may comprise other devices and systems. In embodiments, each of tanks 20-28 may comprise any device suitable to hold the respective cleaning solution and wafer(s) therein. For example, each of tanks 20-28 may comprise a container, bin, receptacle, cartridge, tub, carrier, box, and/or vessel with side walls.

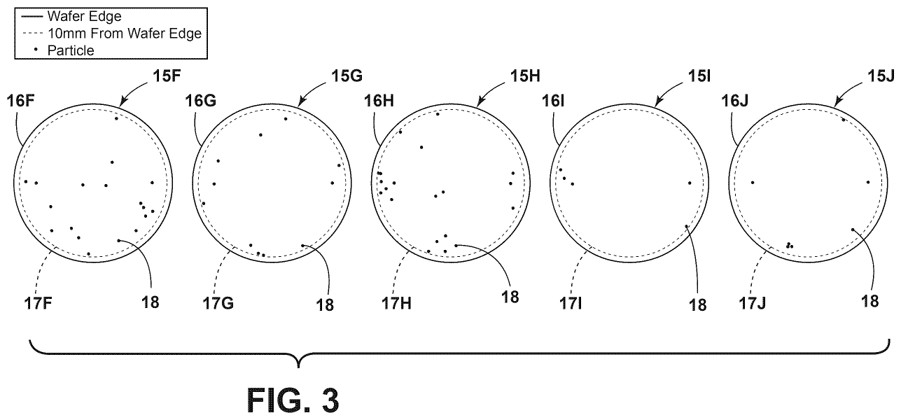

With further reference to FIG. 3, exemplary test wafers 15F-15J were cleaned utilizing the exemplary process 10 shown in FIG. 2 and then scanned for particles using the ZScanner™ 800 scanning device. The particles 18 with a size greater than or equal to 5 microns that remained on the wafers in the area of interest (i.e. the area inside dashed lines 17F-17J) after the cleaning of process 10 are shown in FIG. 3. By comparing the comparative cleaning process of FIG. 1 with the exemplary cleaning process of FIG. 3, the exemplary wafers 15F-15J contained much fewer particles 18 than comparative wafers 15A-15E on their respective surfaces. After being exposed to cleaning process 10, the exemplary wafers 15F-15J only had about 10 particles 18 per wafer with a size of greater than or equal to 5 microns inside dashed lines 17F-17J. Thus, the exemplary cleaning process disclosed herein, which includes the use of the first aqueous solution (the PCD mixture), greatly reduced the number of abrasive particles on the surfaces of the test wafers.

The wafers cleaned by process 10, as disclosed herein, may be comprised of a glass or glass-ceramic material such as, for example, phosphate and/or silicate glass, including modified forms thereof (e.g., borosilicates, borophosphates, aluminosilicates, aluminophosphates, glass doped with alkali or alkaline earth metals, etc.). Other exemplary glass materials include, for example, fused silica, soda lime glass, alkali or alkaline earth silica glass, Gorilla® glass (available from Corning Incorporated). Representative compositions of glasses are provided in U.S. Pat. Nos. 11,802,073; 11,472,731; 11,479,499; and 11,485,676; and also in U.S. Published Patent Application Nos. 20220073409, 20220073410, 20230339803, 20230339801, and 20230303426, the disclosures of which are incorporated by reference herein. The glass material may include one or more high-index modifiers to increase the refractive index of the glass. Exemplary high-index modifiers include, for example, TiO₂, Nb₂O₅, Bi₂O₃, WO₃, and rare earth oxides (e.g., La₂O₃, Y₂O₃, Gd₂O₃).

The refractive index of the wafers may be, for example, about 1.60 or greater, or about 1.65 or greater, or about 1.70 or greater, or about 1.75 or greater, or about 1.80 or greater, or about 1.85 or greater, or about 1.90 or greater, or about 1.95 or greater, or about 2.00 or greater, or about 2.10 or greater, or about 2.20 or greater, or about 2.30 or greater, or about 2.40. Additionally or alternatively, the refractive index of the wafers may be about 2.40 or less, or about 2.30 or less, or about 2.20 or less, or about 2.10 or less, or about 2.00 or less, or about 1.95 or less, or about 1.90 or less, or about 1.85 or less, or about 1.80 or less, or about 1.75 or less, or about 1.70 or less, or about 1.65 or less, or about 1.60 or less. In embodiments, the refractive index is in a range from about 1.60 to about 2.40, or about 1.65 to about 2.30, or about 1.70 to about 2.20, or about 1.75 to about 2.10, or about 1.75 to about 2.00, or about 1.80 to about 1.95, or about 1.85 to about 1.90, or about 1.90 to about 2.10, or any combination of ranges encompassing these endpoints.

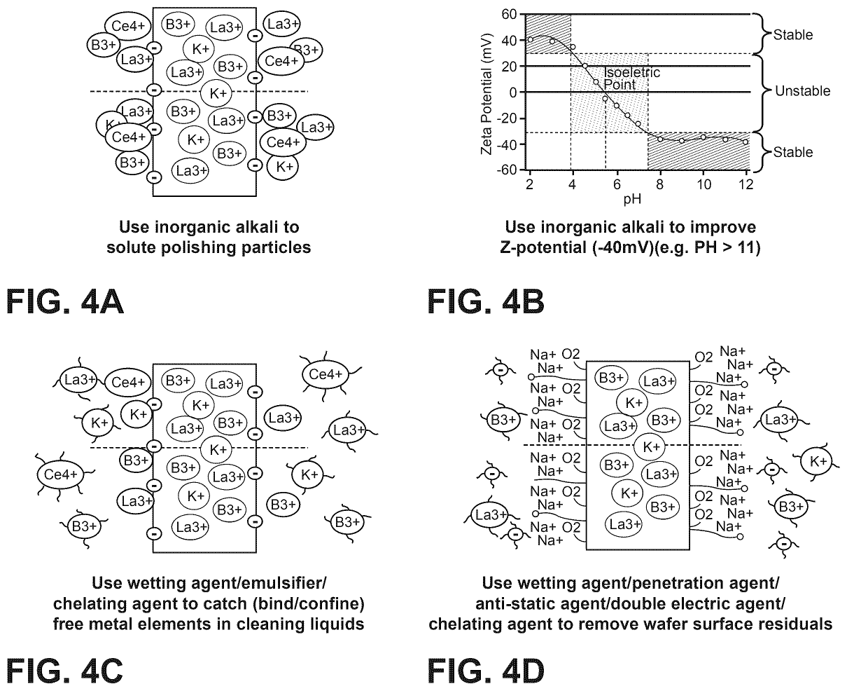

The functions of the chemical additives of the first, second, and third detergents D1, D2, and D3 are illustrated in FIGS. 4A-10 and discussed below.

As shown in FIG. 4A, the inorganic alkali (pH modifier) of the first detergent D1 and the second detergent D2 is used to solute polishing particles, which may comprise the various cations shown in FIG. 4A. It will be understood that the various cations shown in FIG. 4A may not be present in every process, and additional cations may also be present in some processes. The inorganic alkali of the first and second detergents D1, D2 also improves (reduces) the zeta potential as shown in FIG. 4B. In particular, the inorganic alkali increases the pH of the solution to allow for the solubilization of impurities on the wafer surface, which improves the zeta potential.

As shown in FIG. 4C, the wetting agents, emulsifiers, and chelating agents of the first, second and third detergents D1, D2, D3 act as surfactants thereby encouraging the suspension of particles, such as impurities, metals, and residuals in the solution. The emulsifiers are amphiphilic, meaning the molecules contain both a hydrophilic (water-soluble) and hydrophobic (non-polar soluble). Therefore, the emulsifiers can also act on the water surface to help wet the surface by reducing the surface tension. The wetting agents, emulsifiers, and chelating agents are able to coordinate non-covalently to these impurities, isolating them from the solution and surface.

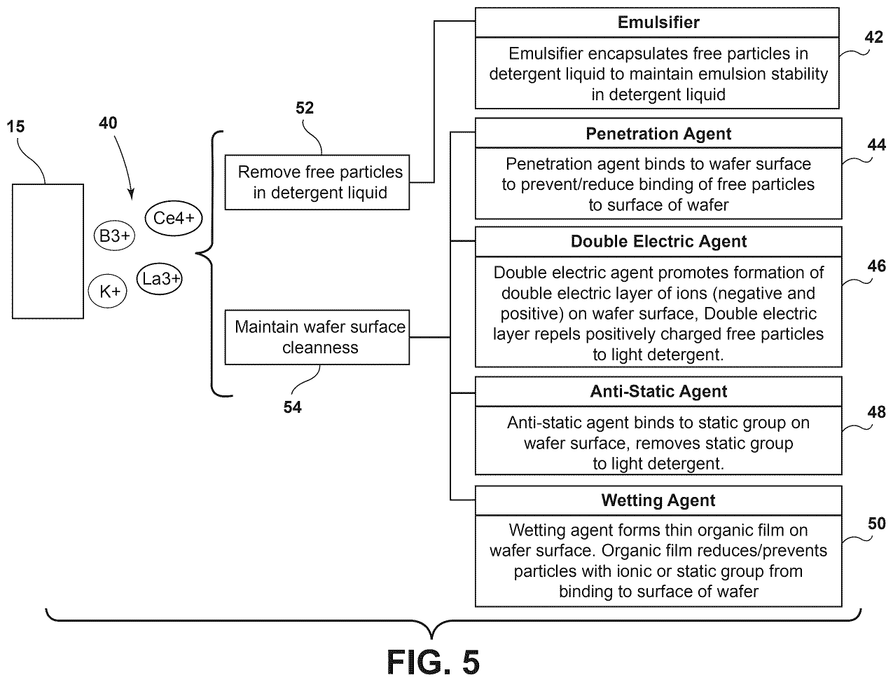

With reference to FIG. 4D, the wetting agents, penetration agents, anti-static agents, double electric agents, and chelating agents of the first, second, and third detergents D1, D2, D3 are used to remove wafer surface residuals by increasing solubilization of the residuals. FIG. 5 is a schematic showing the functions of the first aqueous solution (the PCD mixture) and the accompanying components to accomplish such. In particular, the detergents of the first aqueous solution should be capable of removing free particles in the detergent liquid 52 and maintaining water surface cleanness of the liquid detergent 54. The emulsifier of the second detergent D2 provides the capability to remove the free particles in the detergent liquid. As shown with reference numeral 42 and as discussed further below, the emulsifier encapsulates free particles 40 in the detergent liquid to maintain emulsion stability in the detergent liquid whereby the encapsulated particles can be removed by filtration. As shown with reference numerals 44-50 and as discussed further below, the penetration agent, double-electric agent, anti-static agent, and wetting agent provide the capability to maintain water surface cleanness in the detergent liquid.

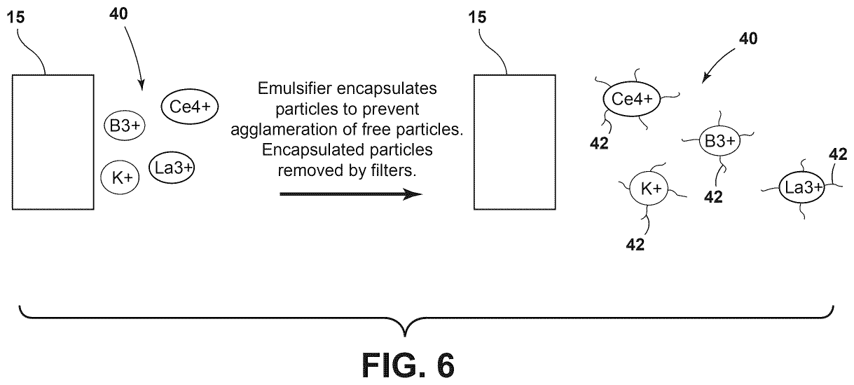

With reference to FIG. 6, the emulsifier 42 encapsulates smaller particles in the detergent liquid to prevent or reduce agglomeration. Specifically, due to high surface potential energy, small particles 40 may agglomerate and form larger particles, and the larger particles may adhere to the surface of the wafer. The emulsifier 42 bonds to and/or encapsulates free particles 40 in the detergent liquid to inhibit or prevent agglomeration of free particles 40 that could otherwise result in formation of larger particles. The particles 40 that are encapsulated by the emulsifier may be removed from the detergent liquid by the filtration systems of the tanks.

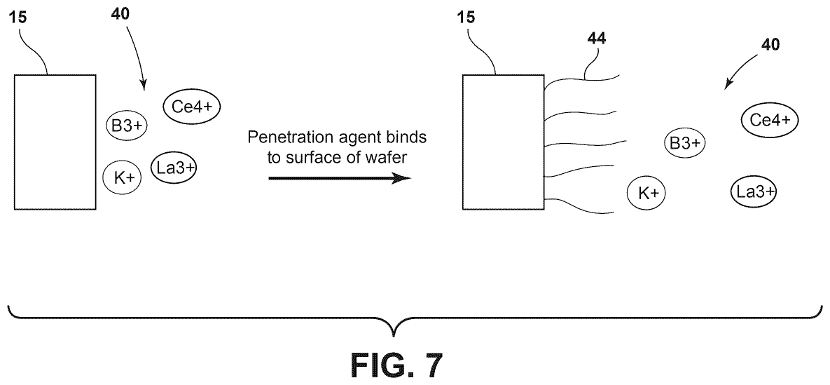

With reference to FIG. 7, free particles 40 in the detergent liquid may comprise an ionic group (e.g. positive electric charge) whereby the particles 40 tend to attach or bind to the surface(s) of wafer 15. However, the penetration agent 44 binds to the surface(s) of wafer 15, thereby preventing the free particles 40 from moving to the surface(s) of wafer 15. The penetration agent 44 in the detergent liquid thereby reduces or prevents binding of particles 40 to the surface(s) of wafer 15. The particles 40 may then be removed from the detergent liquid by the filtrations systems of the tanks.

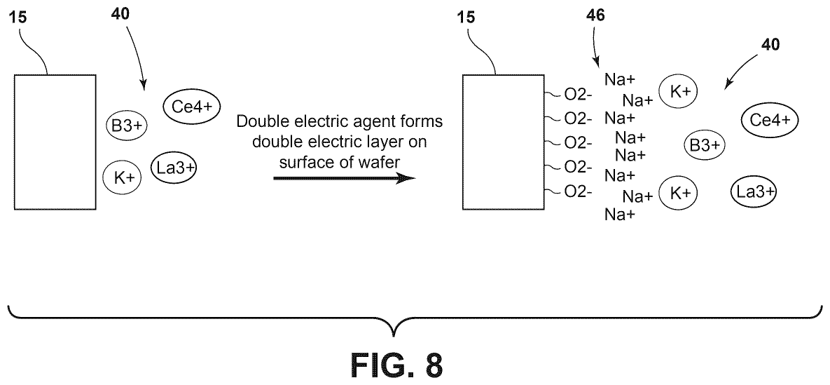

With reference to FIG. 8, free particles 40 having an ionic group (e.g. positive electric charge) may tend to attach or bind to the surface(s) of wafer 15. However, the double electric agent forms a double electric layer 46 on wafer 15 whereby the outer portion of the double electric layer has the same electrical charge (positive in this example) as the particles 40 to repel the free particles 40 from the surface(s) of wafer 15. The free particles 40 may then be removed from the detergent liquid by the filtration systems of the tanks. As discussed above, the pH value of the detergent liquid utilized in connection with the double electric agent is greater than or equal to 11, in embodiments, to facilitate the formation and/or effectiveness of the double electric layer 46.

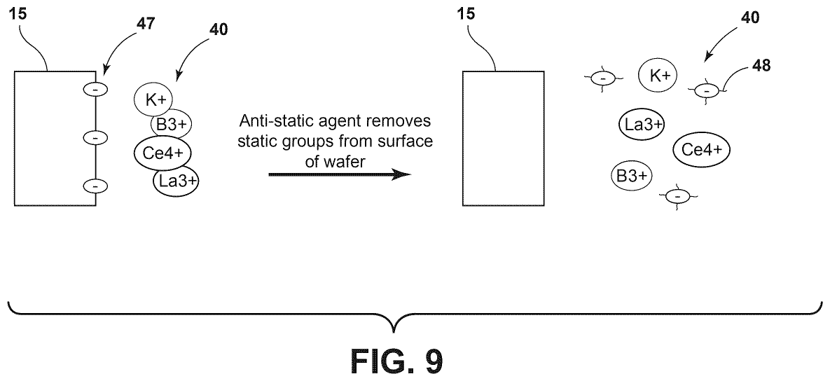

With reference to FIG. 9, free particles 40 having a static group (e.g. positive electric charge) may also attach to the surface(s) of wafer 15 due to static groups or charges 47 (e.g. negative electrical charge) on the wafer surface(s). In the example of FIG. 9, particles 40 have positive electrical charges and the static groups 47 have a negative electric charge. However, at least some of the static groups 47 may have a positive electric charge, and at least some particles 40 may have negative electrical charges. The molecules of the anti-static agent 48 bind to the static groups or charges 47 to thereby remove the static groups 47 from the surface(s) of wafer 15. After the static groups 47 are removed from the surface of wafer 15, the static groups 47 are disposed in solution in the detergent liquid. This reduces or eliminates binding of particles 40 to the wafer 15 that could otherwise result from attraction of particles 40 to static groups 47 on the surface of wafer 15. The static groups 47 may be removed from the detergent liquid by the filtration systems of the tanks.

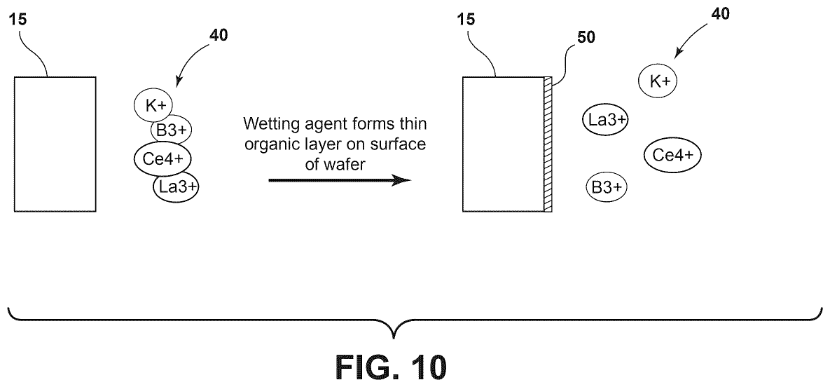

With reference to FIG. 10, free particles 40 having ionic and/or static groups (e.g. positive electric charge) may tend to bind to the surface(s) of wafer 15. The wetting agent forms a thin organic layer 50 on wafer 15 to prevent the surface(s) of wafer 15 from drying, thereby maintaining a wet surface to prevent binding of free particles 40 on the surface of wafer 15.

According to a first aspect, a method of removing particles from a surface of a wafer is disclosed, the method comprising cleaning the wafer with an aqueous first solution comprising a mixture of a first detergent, a second detergent, and a third detergent. The first detergent comprising an aqueous solution comprising a pH buffer, an inorganic alkali, a wetting and emulsifying agent, and a chelating agent, the second detergent comprising an aqueous solution comprising an emulsifier, a pH buffer, an inorganic alkali, a double electric agent, and a chelating agent, and the third detergent comprising an aqueous solution comprising a pH buffer, a wetting and penetration agent, an antistatic and emulsifying agent, and a chelating agent.

According to a second aspect, the method of the first aspect, further comprising after cleaning the wafer with the aqueous first solution, cleaning the wafer with at least one of the first detergent, the second detergent, and the third detergent.

According to a third aspect, the method of the first or second aspect, further comprising after cleaning the wafer with the aqueous first solution, cleaning the wafer with the first detergent, the second detergent, and the third detergent.

According to a fourth aspect, the method of any one of the first through third aspects, wherein the pH buffer of at least one of the first detergent, the second detergent, and the third detergent comprises sodium carbonate, and the chelating agent of at least one of the first detergent, the second detergent, and the third detergent comprises C₁₀H₁₆N₂O₈.

According to a fifth aspect, the method of any one of the first through fourth aspects, wherein the inorganic alkali of at least one of the first detergent and the second detergent comprises sodium hydroxide.

According to a sixth aspect, the method of any one of the first through fifth aspects, wherein the wetting and emulsifying agent of the first detergent comprises C₄H₆O₄·2Na.

According to a seventh aspect, the method of any one of the first through sixth aspects, wherein the emulsifier of the second detergent comprises C₁₈H₃₄O₂·Na.

According to an eighth aspect, the method of any one of the first through seventh aspects, wherein the double electric agent of the second detergent comprises (C₃H₄O₃)ₓ·xNa.

According to a ninth aspect, the method of any one of the first through eighth aspects, wherein the wetting and penetration agent of the third detergent comprises (C₂H₄O)ₙC₁₈H₃₈O and/or C₃H₈O₃·3(C₃H₆O·C₂H₄O)ₓ.

According to a tenth aspect, the method of any one of the first through ninth aspects, wherein the antistatic and emulsifying agent of the third detergent comprises C₁₂H₂₆O·xH₃O₄P·xK.

According to an eleventh aspect, the method of any one of the first through tenth aspects, wherein the aqueous first solution comprises about 15 wt. % to about 35 wt. % of the first detergent, about 15 wt. % to about 35 wt. % of the second detergent, and about 40 wt. % to about 60 wt. % of the third detergent.

According to a twelfth aspect, the method of any one of the first through eleventh aspects, wherein the aqueous first solution is disposed in a tank and the method further comprising immersing the wafer in the aqueous first solution in the tank.

According to a thirteenth aspect, the method of any one of the first through twelfth aspects, wherein the first detergent comprises a pH from about 11 to about 14.

According to a fourteenth aspect, the method of any one of the first through thirteenth aspects, further comprising cleaning the wafer with deionized water (DIW), after cleaning the wafer with DIW, cleaning the wafer with the first detergent in an aqueous solution, after cleaning the wafer with the first detergent, cleaning the wafer with at least one of the second detergent and the third detergent in an aqueous solution, and cleaning the wafer with isopropyl alcohol.

According to a fifteenth aspect, a cleaning system for removing polishing particles from surfaces of wafers that have been polished is disclosed, the cleaning system comprising a tank containing an aqueous first solution comprising a mixture of a first detergent, a second detergent, and a third detergent. The first detergent comprising an aqueous solution comprising a pH buffer, an inorganic alkali, a wetting and emulsifying agent, and a chelating agent, the second detergent comprising an aqueous solution comprising an emulsifier, a pH buffer, an inorganic alkali, a double electric agent, and a chelating agent, and the third detergent comprising an aqueous solution comprising a pH buffer, a wetting and penetration agent, an antistatic and emulsifying agent, and a chelating agent.

According to a sixteenth aspect, the cleaning system of the fifteenth aspect, further comprising a first tank containing deionized water (DIW), a tank containing the first detergent in an aqueous solution, a second tank containing DIW, a tank containing the second detergent in an aqueous solution, a tank containing the third detergent in an aqueous solution, a third tank containing DIW, and a tank containing isopropyl alcohol.

According to a seventeenth aspect, the cleaning system of the fifteenth aspect or the sixteenth aspect, wherein the pH buffer of at least one of the first detergent, the second detergent, and the third detergent comprises sodium carbonate, and the chelating agent of at least one of the first detergent, the second detergent, and the third detergent comprises C₁₀H₁₆N₂O₈.

According to an eighteenth aspect, the cleaning system of any one of the fifteenth through seventeenth aspects, wherein the inorganic alkali of at least one of the first detergent and the second detergent comprises sodium hydroxide.

According to a nineteenth aspect, the cleaning system of any one of the fifteenth through eighteenth aspects, wherein the wetting and emulsifying agent of the first detergent comprises C₄H₆O₄·2Na.

According to a twentieth aspect, the cleaning system of any one of the fifteenth through nineteenth aspects, wherein the emulsifier of the second detergent comprises C₁₈H₃₄O₂·Na.

According to a twenty-first aspect, the cleaning system of any one of the fifteenth through twentieth aspects, wherein the double electric agent of the second detergent comprises (C₃H₄O₃)ₓ·xNa.

According to a twenty-second aspect, the cleaning system of any one of the fifteenth through twenty-first aspects, wherein the wetting and penetration agent of the third detergent comprises (C₂H₄O)ₙC₁₈H₃₈O and/or C₃H₈O₃·3(C₃H₆O·C₂H₄O)ₓ.

According to a twenty-third aspect, the cleaning system of any one of the fifteenth through twenty-second aspects, wherein the antistatic and emulsifying agent of the third detergent comprises C₁₂H₂₆O·xH₃O₄P·xK.

According to a twenty-fourth aspect, the cleaning system of any one of the fifteenth through twenty-third aspects, wherein the aqueous first solution comprises about 15 wt. % to about 35 wt. % of the first detergent, about 15 wt. % to about 35 wt. % of the second detergent, and about 40 wt. % to about 60 wt. % of the third detergent.

Many variations and modifications may be made to the above-described embodiments/aspects of the disclosure without departing substantially from the spirit and various principles of the disclosure. All such modifications and variations are intended to be included herein within the scope of this disclosure and protected by the following claims.

What is claimed is:

1. A method of removing particles from a surface of a wafer, the method comprising:
cleaning the wafer with an aqueous first solution comprising a mixture of a first detergent, a second detergent, and a third detergent,
the first detergent comprising an aqueous solution comprising a pH buffer, an inorganic alkali, a wetting and emulsifying agent, and a chelating agent;
the second detergent comprising an aqueous solution comprising an emulsifier, a pH buffer, an inorganic alkali, a double electric agent, and a chelating agent; and
the third detergent comprising an aqueous solution comprising a pH buffer, a wetting and penetration agent, an antistatic and emulsifying agent, and a chelating agent.

2. The method of claim 1, further comprising:
after cleaning the wafer with the aqueous first solution, cleaning the wafer with at least one of the first detergent, the second detergent, and the third detergent.

3. The method of claim 1, further comprising:
after cleaning the wafer with the aqueous first solution, cleaning the wafer with the first detergent, the second detergent, and the third detergent.

4. The method of claim 1, wherein:
the pH buffer of at least one of the first detergent, the second detergent, and the third detergent comprises sodium carbonate, and
the chelating agent of at least one of the first detergent, the second detergent, and the third detergent comprises C₁₀H₁₆N₂O₈.

5. The method of claim 1, wherein:
the inorganic alkali of at least one of the first detergent and the second detergent comprises sodium hydroxide.

6. The method of claim 1, wherein:
the wetting and emulsifying agent of the first detergent comprises C₄H₆O₄·2Na.

7. The method of claim 1, wherein:
the emulsifier of the second detergent comprises C₁₈H₃₄O₂·Na.

8. The method of claim 1, wherein:
the double electric agent of the second detergent comprises (C₃H₄O₃)ₓ·xNa.

9. The method of claim 1, wherein:
the wetting and penetration agent of the third detergent comprises (C₂H₄O)ₙC₁₈H₃₈O and/or C₃H₈O₃·3(C₃H₆O·C₂H₄O)ₓ.

10. The method of claim 1, wherein:
the antistatic and emulsifying agent of the third detergent comprises C₁₂H₂₆O·xH₃O₄P·xK.

11. The method of claim 1, wherein:
the aqueous first solution comprises about 15 wt. % to about 35 wt. % of the first detergent, about 15 wt. % to about 35 wt. % of the second detergent, and about 40 wt. % to about 60 wt. % of the third detergent.

12. The method of claim 1, wherein:
the aqueous first solution is disposed in a tank and the method further comprising immersing the wafer in the aqueous first solution in the tank.

13. The method of claim 1, wherein:
the first detergent comprises a pH from about 11 to about 14.

14. The method of claim 1, further comprising:
cleaning the wafer with deionized water (DIW);
after cleaning the wafer with DIW, cleaning the wafer with the first detergent in an aqueous solution;
after cleaning the wafer with the first detergent, cleaning the wafer with at least one of the second detergent and the third detergent in an aqueous solution; and
cleaning the wafer with isopropyl alcohol.

15. A cleaning system for removing polishing particles from surfaces of wafers that have been polished, the cleaning system comprising:
a tank containing an aqueous first solution comprising a mixture of a first detergent, a second detergent, and a third detergent,
the first detergent comprising an aqueous solution comprising a pH buffer, an inorganic alkali, a wetting and emulsifying agent, and a chelating agent;
the second detergent comprising an aqueous solution comprising an emulsifier, a pH buffer, an inorganic alkali, a double electric agent, and a chelating agent; and
the third detergent comprising an aqueous solution comprising a pH buffer, a wetting and penetration agent, an antistatic and emulsifying agent, and a chelating agent.

16. The cleaning system of claim 15, further comprising:
a first tank containing deionized water (DIW);
a tank containing the first detergent in an aqueous solution;
a second tank containing DIW;
a tank containing the second detergent in an aqueous solution;
a tank containing the third detergent in an aqueous solution;
a third tank containing DIW; and
a tank containing isopropyl alcohol.

17. The cleaning system of claim 15, wherein:
the pH buffer of at least one of the first detergent, the second detergent, and the third detergent comprises sodium carbonate, and
the chelating agent of at least one of the first detergent, the second detergent, and the third detergent comprises C₁₀H₁₆N₂O₈.

18. The cleaning system of claim 15, wherein:
the inorganic alkali of at least one of the first detergent and the second detergent comprises sodium hydroxide.

19. The cleaning system of claim 15, wherein:
the wetting and emulsifying agent of the first detergent comprises C₄H₆O₄·2Na.

20. The cleaning system of claim 15, wherein:
the emulsifier of the second detergent comprises C₁₈H₃₄O₂·Na.
